(19) United States
(12) Patent Application Publication
(10) Pub. No.: US 2011/0042711 A1
(43) Pub. Date: Feb. 24, 2011

(54) III-NITRIDE SEMICONDUCTOR LIGHT EMITTING DEVICE AND METHOD FOR FABRICATING THE SAME

(75) Inventors: Yu-hang CHOI, Gyeonggi-do (KR); Chae-seok LIM, Gyeonggi-do (KR); Keuk KIM, Gyeonggi-do (KR); Chi-kwon PARK, Gyeonggi-do (KR)

Correspondence Address: HUSCH BLACKWELL LLP, 190 Carondelet Plaza, Suite 600, ST. LOUIS, MO, 63105, US

(73) Assignee: WOOREE LST CO., LTD., Gyeonggi-do (KR)

(21) Appl. No.: 12/650,626

(22) Filed: Dec. 31, 2009

(30) Foreign Application Priority Data
Aug. 18, 2009 (KR) 10-2009-0076076

(51) Int. Cl. H01L 33/32; H01L 33/00

(52) U.S. Cl. 257/103; 438/39; 257/E33.023

(57) ABSTRACT

The present invention relates to III-nitride semiconductor light emitting device and a method for fabricating the same. The III-nitride semiconductor light emitting device includes: a substrate; a plurality of III-nitride semiconductor layers grown over the substrate and including an active layer for generating light by recombination of electrons and holes; and a protrusion formed on a surface of the substrate over which the semiconductor layers are to be grown, a section of the protrusion which is in parallel to the growth direction of the semiconductor layers being formed in a triangular shape.

### CROSS-REFERENCE TO RELATED APPLICATION

This application claims the benefit of Korean Patent Application No. 10-2009-0076076 filed on Aug. 18, 2009, which is hereby incorporated by reference as if fully set forth herein.

### BACKGROUND OF THE INVENTION

The present invention relates generally to a III-nitride semiconductor light emitting device and a method for fabricating the same, and more particularly, to a III-nitride semiconductor light emitting device and a method for fabricating the same which can improve the external quantum efficiency and reduce crystal defects of a III-nitride semiconductor.

FIG. 1 illustrates an example of conventional III-nitride semiconductor light emitting device. The III-nitride semiconductor light emitting device includes a substrate 100, a buffer layer 200 grown on the substrate 100, an n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, an n-side electrode 800 formed on the n-type nitride semiconductor layer 300 exposed by mesa-etching the p-type nitride semiconductor layer 500 and the active layer 400, and a protection film 900.

FIG. 2 illustrates an example of a light emitting device disclosed in International Publication Nos. WO 02/75821 and WO 03/10831, which shows a process of growing III-nitride semiconductor layer 41 on a patterned substrate 40.

The III-nitride semiconductor layers 41 are grown on concave and convex portions of the patterned substrate 40, and then brought into contact with each other. After the growth is facilitated in the contact regions, the III-nitride semiconductor layer 40 has a flat surface. Use of the patterned substrate 40 makes it possible to scatter light to improve the external quantum efficiency and to reduce crystal defects to improve quality of the III-nitride semiconductor layer 41.

FIG. 3 illustrates an example of a light emitting device disclosed in International Publication No. WO 03/10831 and U.S. Patent Publication No. 2005-082546, which suggests a technique of forming circular protrusions 51 on a substrate 50 and growing a III-nitride semiconductor layer 52 thereon. As the growth does not occur on a top surface of the substrate 50 due to the circular convex portions 51, the flat III-nitride semiconductor layer 52 is formed earlier. Aside from this, the III-nitride semiconductor layer 52 has the same effect as that of the III-nitride semiconductor layer 41 shown in FIG. 2.

There is thus a need for an improved III-nitride semiconductor light emitting device and fabricating method thereof to resolve the aforementioned issues. The present invention provides an advance in the art by providing III-nitride semiconductor light emitting device and fabricating method thereof.

Further objectives and advantages of the present invention will become apparent from a careful reading of a detailed description provided herein below, with appropriate reference to the accompanying drawings.

### SUMMARY OF THE INVENTION

This section provides a general summary of the disclosure and is not a comprehensive disclosure of its full scope or all of its features.

According to one aspect of the present invention, there is provided a III-nitride semiconductor light emitting device, including: a substrate; a plurality of III-nitride semiconductor layers grown over the substrate and including an active layer for generating light by recombination of electrons and holes; and a protrusion formed on a surface of the substrate over which the semiconductor layers are to be grown, a section of the protrusion which is in parallel to the growth direction of the semiconductor layers being formed in a triangular or conical shape.

According to another aspect of the present invention, there is provided a method for fabricating a III-nitride semiconductor light emitting device, the method including: a mask formation step of forming a first etch mask for forming a protrusion on a substrate and a second etch mask for forming an irregular portion on a surface of the protrusion; and an etching step of forming the protrusion and the irregular portion by dry etching.

The advantageous effects of the present invention will be described in the latter part of the best mode for carrying out the invention.

### BRIEF DESCRIPTION OF THE DRAWINGS

FIG. 1 is a view of an example of a conventional III-nitride semiconductor light emitting device.

FIG. 2 is a view of an example of a light emitting device disclosed in International Publication Nos. WO 02/75821 and WO 03/10831.

FIG. 3 is a view of an example of a light emitting device disclosed in International Publication No. WO 03/10831 and U.S. Patent Publication No. 2005-082546.

FIG. 4 is a view of an embodiment of a III-nitride semiconductor light emitting device according to the present invention.

FIG. 5 is a photograph of an example of a substrate according to the present invention.

FIGS. 6 to 8 are photographs of the light proceeding into a sapphire substrate using a simulator and graphs of the amount of the emitted light versus time.

FIG. 9 is a view of another example of the substrate according to the present invention.

FIG. 10 is a view of a further example of the substrate according to the present invention.

FIG. 11 is an explanatory view of an embodiment of a method for fabricating a III-nitride semiconductor light emitting device according to the present invention.

FIG. 12 is an explanatory view of another example of a method for forming an etch mask according to the present invention.

FIG. 13 is an explanatory view of a further example of the method for forming the etch mask according to the present invention.

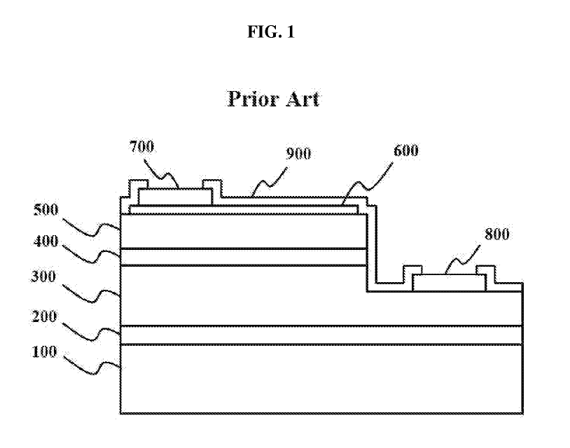

It should be understood that the drawings are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted. It should be understood, of course, that the invention is not necessarily limited to the particular embodiments illustrated herein. Like numbers utilized throughout the various Figures designate like or similar parts or structure.

### DETAILED DESCRIPTION OF THE INVENTION

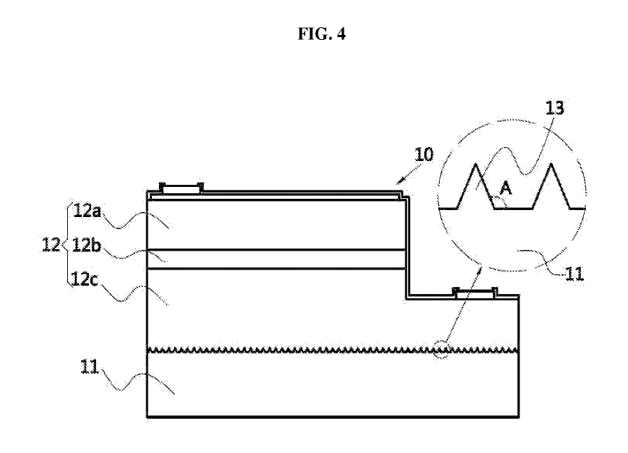

FIG. 4 illustrates one embodiment of III-nitride semiconductor light emitting device according to the present invention. The III-nitride semiconductor light emitting device 10 (hereinafter, referred to as ‘ light emitting device’) includes a substrate 11, III-nitride semiconductor layers 12 (hereinafter, referred to as ‘ semiconductor layers’) wherein the substrate includes a series of elongated protrusions 13 formed on the substrate 11, the series of protrusions are spaced apart each other.

The semiconductor layers 12 comprise a plurality of semiconductor layers 12a, 12b and 12c, including an active layer 12b for generating light by recombination of electrons and holes.

The semiconductor layers 12 may be grown on a buffer layer formed on the substrate 11 or directly on the substrate 11 without the buffer layer.

The protrusions 13 are formed on a top surface of the substrate 11 over which the semiconductor layers 12 are stacked, and sections of the protrusions 13 which are in parallel to the growth direction of the semiconductor layers 12, i.e., vertical sections of the light emitting device 10 are formed in a triangular or conical shape.

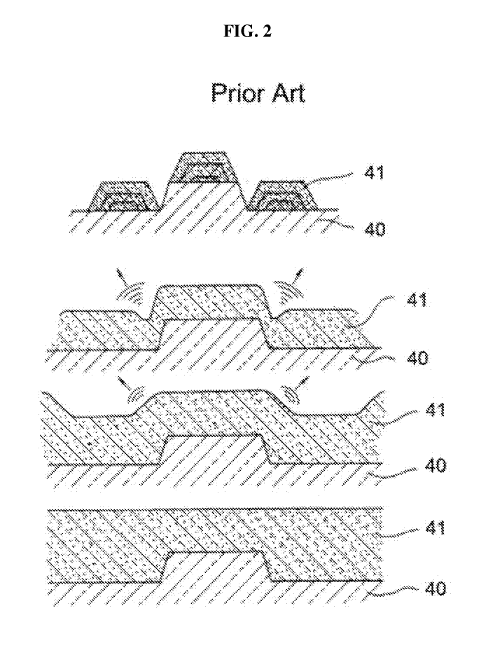

Unlike the planar top surface of the convex portion shown in FIG. 2, an upper portion of the protrusion 13 includes a substantially conical or triangular top point. Therefore, there is an advantage in that the semiconductor layer 12 can be planarized fast. Further, other types of protrusions or projections having a point top portion can also be used in the present invention without departing from the spirit and scope of the invention.

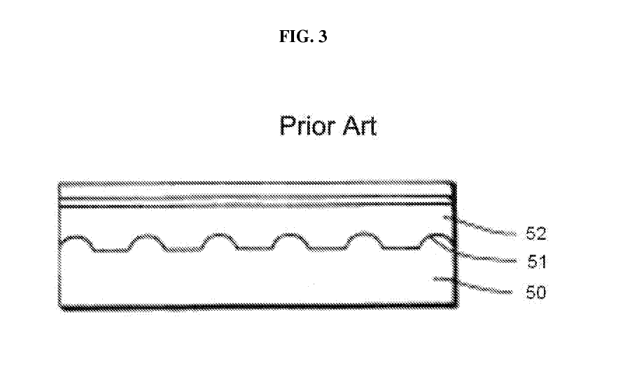

In addition, unlike the semispherical convex portion shown in FIG. 3, an angle A of an outer surface of the protrusion 13 to a horizontal surface of the substrate 11 is an obtuse angle. Accordingly, the semiconductor layer 12 is easily grown in the intersection region of the outer surface of the protrusions 13 and the horizontal surface of the substrate 11. As a result, there is an advantage in that crystal defects generated during the growth of the semiconductor layer 12 can be reduced.

Moreover, the protrusions 13 serve to scatter the light generated in the active layer 12b to emit the light to the outside of the light emitting device 10.

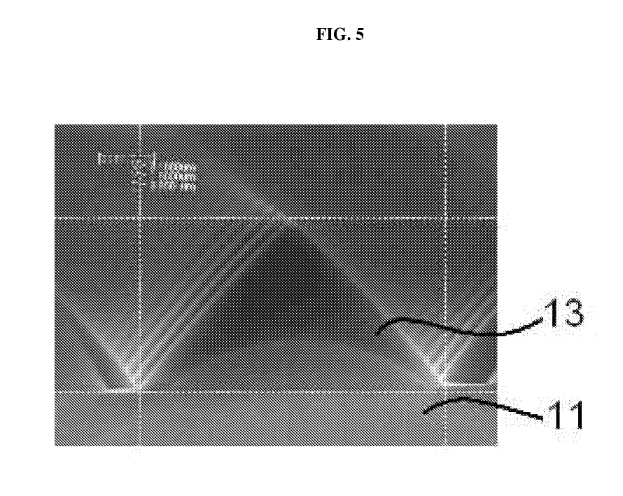

FIG. 5 illustrates a photograph of an example of the substrate according to the present invention. The respective protrusions 13 formed on the substrate 11 can have a generally conical or triangular shaped top segment. In this case, since an upper part of the protrusion 13 has a sharp point, a semiconductor layer 12 is grown in the order of a bottom surface of a groove defined between the protrusions 13, a circumferential surface of the protrusion 13, and the apex of the protrusion 13. Further, unlike the convex portion of FIG. 2, the semiconductor layer 12 is not grown on a top surface of the protrusion 13. Therefore, there is an advantage in that the semiconductor layer 12 can be planarized fast.

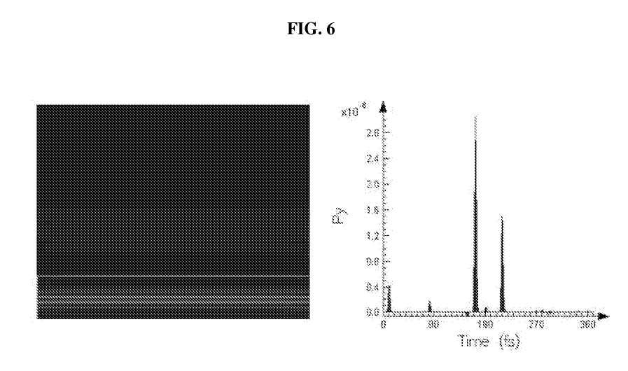

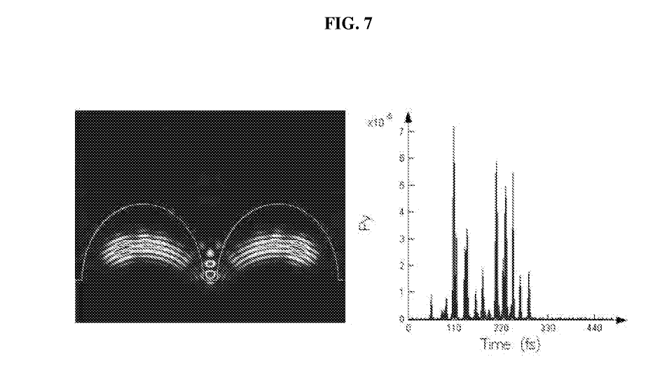

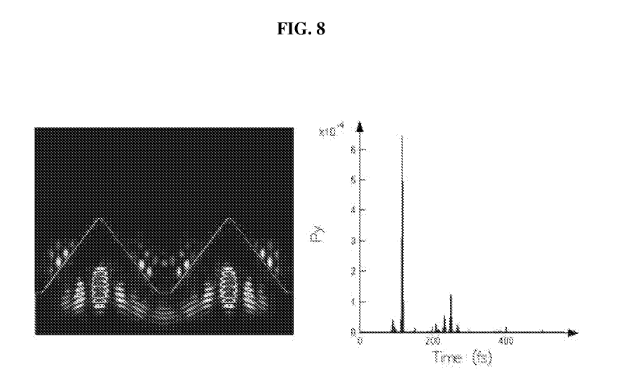

FIGS. 6-8 are photographs of the light proceeding into a sapphire substrate using a simulator and graphs of the amount of the emitted light versus time. FIG. 6 shows a case where a protrusion is not formed, FIG. 7 shows a case where a protrusion is formed in a semispherical shape, and FIG. 8 shows a case where a protrusion is formed in the conical or triangular shape.

In the graphs of FIGS. 6-8, the axis of ordinates represents the amount of the emitted light and the axis of abscissa represents the time consumed to emit light.

In FIG. 6, most of the light is emitted near 170 fs. Afterwards, light is circulated in the light emitting device by scattering and emitted.

In FIG. 7, light is emitted near 110 fs which is earlier than that of FIG. 6 (the earlier light is emitted, the greater the effect). The amount of the light is 25 times larger than that of FIG. 6. However, there is a large amount of the light circulated in the light emitting device and emitted.

In FIG. 8, most of the light is emitted in a time zone similar to that of FIG. 7. However, the amount of the light is 10 times larger than that of FIG. 7. In addition, there is a small amount of the light circulated in the light emitting device and emitted.

Accordingly, it is appreciated that the conical or triangular protrusion is more advantageous in terms of light emission than the semispherical protrusion or the absence of the protrusion.

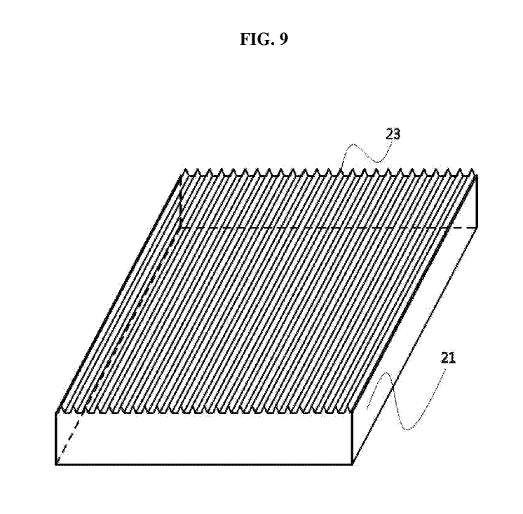

FIG. 9 illustrates another example of the substrate according to the present invention. Protrusions 23 may be located on a substrate 21 to be perpendicular to the growth direction of semiconductor layers 12 and formed in the shape of a triangular pillar, i.e., a stripe with a triangular section.

In this case, since the top portion of the protrusion 23 forms a sharp or narrow line, the semiconductor layer 12 is not grown on the top surface of the protrusion 23. Therefore, there is an advantage in that the semiconductor layer 12 can be planarized fast.

It is preferable to form protrusion 23 in the conical triangular shape in terms of the external quantum efficiency because it can obtain scattering surfaces in various directions.

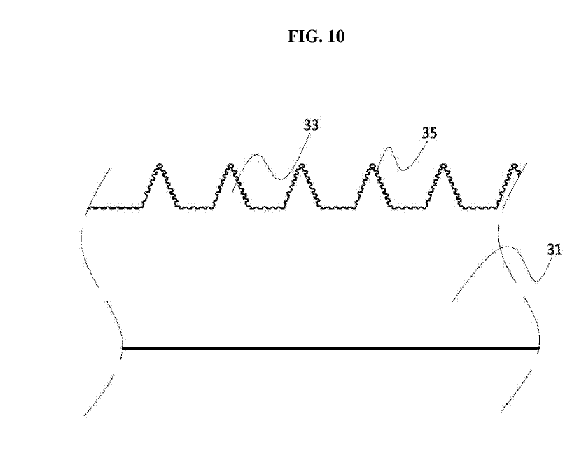

FIG. 10 illustrates a further example of the substrate according to the present invention. Irregular portions 35 are formed on surfaces of protrusions 33 formed on a substrate 31. As the irregular portion 35 is formed on the surface of the protrusion 33, it is relatively smaller than the protrusion 33.

In addition, the irregular portion 35 may be formed on the surface of the substrate 31 between the protrusions 33 as well as on the surface of the protrusion 33. As a result, there is an advantage in that crystal defects generated in the semiconductor layer 12 can be reduced during the growth of the semiconductor layer 12.

Specifically, when the semiconductor layer is grown on the substrates of FIGS. 2 and 3, it is grown on parts of the circumferential surfaces of the convex portions as well as on the bottom or top surfaces of the convex portions. Crystal defects are generated due to the partially-grown semiconductor layer.

However, when the irregular portions 35 are formed on the surfaces of the protrusions 33, the semiconductor layer 12 can be uniformly grown on the circumferential surfaces of the protrusions 33. Therefore, crystal defects of the semiconductor layer 12 can be reduced.

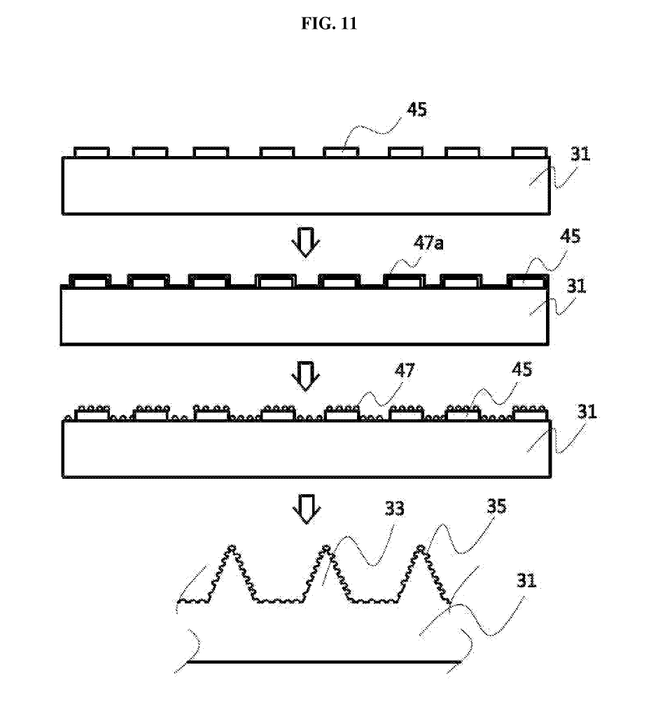

FIG. 11 is an explanatory view of an embodiment of a method for fabricating III-nitride semiconductor light emitting device according to the present invention, which includes a mask formation step and a dry etching step.

The mask formation step is to form a first etch mask 45 for forming protrusions 33 on a substrate 31 and a second etch mask 47 for forming irregular portions 35 on surfaces of the protrusions 33.

The first etch mask 45 may be formed by a photolithography process. That is, photoresist (PR) is coated on the substrate 31 and subjected to exposure and development, thereby forming the first etch mask 45. The second etch mask 47 is formed by a step of forming a material layer 47a and a step of applying heat to the material layer 47a.

The material layer 47a may be formed on the substrate 31 with the first etch mask 45 thereon. The material layer 47a may be formed of a metal material such as Ag or Mg and coated at a thickness of 0.1 to 5 nm.

The step of applying heat to the material layer 47a is provided to re-arrange material particles constituting the material layer 47a. When heat is applied to the material layer 47a, the material particles are re-arranged in a lump shape (e.g., a ball shape) to minimize the surface energy, thereby forming the second etch mask 47.

In addition to Ag and Mg mentioned above, any material containing material particles re-arranged by heat to have a resolution for forming the irregular portions 35 may be used as the material for forming the second etch mask 47.

The dry etching step is provided to form the protrusions 33 and the irregular portions 35 by a dry etching process. The dry etching process may be any one of inductive coupled plasma etching, reactive ion etching, capacitive coupled plasma (CCP) etching, and electron-cyclotron resonance (ECR).

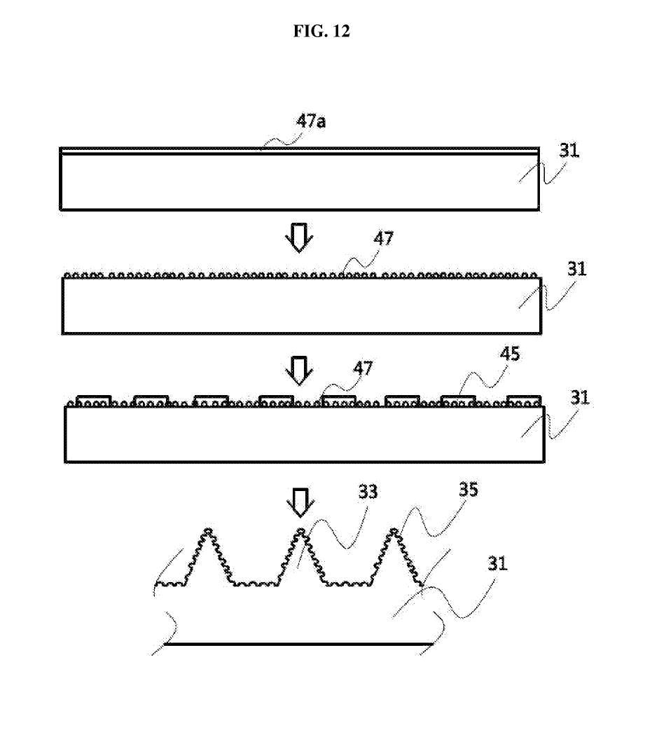

FIG. 12 is an explanatory view of another example of the method for forming the etch mask according to the present invention. A second etch mask 47 may be formed on a substrate 31, and then a first etch mask 45 may be formed thereon.

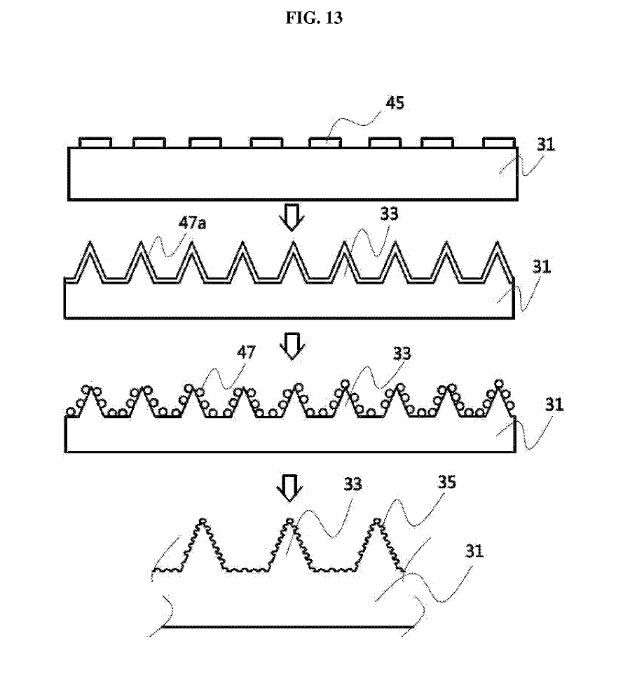

Moreover, FIG. 13 is an explanatory view of a further example of the method for forming the etch mask according to the present invention. A first etch mask 45 may be formed on a substrate 31, protrusions 33 may be formed by an etching process, and a second etch mask 47 may be formed on the protrusions 33. Here, it is apparent that the etching process is not limited to dry etching but includes wet etching. Hereinafter, various exemplary embodiments of the present invention will be described.

(1) A III-nitride semiconductor light emitting device including a substrate with a circular conical protrusion or stripe-shaped protrusion thereon, and semiconductor layers grown over the substrate and including an active layer.

Therefore, since the semiconductor layer is easily grown in the intersection region of the protrusion and the substrate, it is possible to reduce crystal defects generated during the growth, and since the light generated in the active layer is scattered by the protrusion, it is possible to improve the external quantum efficiency.

(2) The III-nitride semiconductor light emitting device of (1), wherein an irregular portion is formed on a surface of the protrusion.

(3) The III-nitride semiconductor light emitting device of either (1) or (2), wherein the irregular portion is formed in a spherical or corrugated shape.

(2) and (3) make it possible to reduce crystal defects generated in the semiconductor layer during the growth of the semiconductor layer.

(4) A method for fabricating a III-nitride semiconductor light emitting device, wherein either a first etch mask for forming a protrusion or a second etch mask for forming an irregular portion is formed, and the other is formed thereon, wherein the second etch mask is formed by a step of forming a material layer and a step of applying heat to the material layer.

This allows the fabrication of a substrate having a protrusion with a fine-size irregular portion thereon. It is thus possible to improve the external quantum efficiency of the light emitting device and reduce crystal defects of a semiconductor layer.

According to one III-nitride semiconductor light emitting device of the present invention, since the light generated in the active layer is scattered by the protrusion, there is an advantage in that the external quantum efficiency can be improved. In addition, since the semiconductor layer is easily grown in the intersection region of the protrusion and the substrate, there is an advantage in that crystal defects generated during the growth can be reduced. Moreover, since the protrusion has a triangular section, the semiconductor layer is not grown on the top surface of the protrusion. There is an advantage in that the semiconductor layer can be planarized fast.

According to another III-nitride semiconductor light emitting device of the present invention, since the semiconductor layer is prevented from being grown on a part of the circumferential surface of the protrusion due to the irregular portion formed on the surface of the protrusion, there is an advantage in that crystal defects of the semiconductor layer can be reduced.

According to the method for fabricating the III-nitride semiconductor light emitting device of the present invention, there is an advantage in that the external quantum efficiency can be improved and crystal defects of the III-nitride semiconductor layer can be effectively reduced by the second etch mask having a greater resolution than that of the etch mask formed by photolithography.

Thus, there has been shown and described several embodiments of a novel invention. As is evident from the foregoing description, certain aspects of the present invention are not limited by the particular details of the examples illustrated herein, and it is therefore contemplated that other modifications and applications, or equivalents thereof, will occur to those skilled in the art.

The terminology used in the description of the invention herein is for the purpose of describing particular embodiments only and is not intended to be limiting of the invention. As used in the description of the embodiments of the invention and the appended claims, the singular forms “a”, “an” and “the” are intended to include the plural forms as well, unless the context clearly indicates otherwise.

Moreover, it will be understood that although the terms first, second and third are used herein to describe various features, elements, regions, layers and/or sections, these features, elements, regions, layers and/or sections should not be limited by these terms. These terms are only used to distinguish one feature, element, region, layer or section from another feature, element, region, layer or section. Thus, a first feature, element, region, layer or section discussed below could be termed a second feature, element, region, layer or section, and similarly, a second without departing from the teachings of the present invention.

The terms “having” and “including” and similar terms as used in the foregoing specification are used in the sense of “optional” or “may include” and not as “required”. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow. The scope of the disclosure is not intended to be limited to the embodiments shown herein, but is to be accorded the full scope consistent with the claims, wherein reference to an element in the singular is not intended to mean “one and only one” unless specifically so stated, but rather “one or more.” All structural and functional equivalents to the elements of the various embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A III-nitride semiconductor light emitting device comprising:
a substrate;
a plurality of III-nitride semiconductor layers grown over said substrate, said plurality of III-nitride semiconductor layers including an active layer for generating light by recombination of electrons and holes; and
a plurality of protrusions formed on a surface of the substrate over which the semiconductor layers are to be grown, a section of the protrusion which is in parallel to the growth direction of the semiconductor layers being formed in a triangular shape.

2. The III-nitride semiconductor light emitting device of claim 1, wherein each of said plurality of protrusions is formed in a conical shape.

3. The III-nitride semiconductor light emitting device of claim 1, further comprising an irregular portion formed on a surface of said protrusions.

4. The III-nitride semiconductor light emitting device of claim 1, wherein the substrate is formed of sapphire, each of said plurality of protrusions is formed in a conical shape, and an irregular portion is formed on a surface of said protrusions.

5. A method for fabricating III-nitride semiconductor light emitting device as recited in claim 3, the method comprising:
a mask formation step of forming a first etch mask for forming a protrusion on a substrate and a second etch mask for forming an irregular portion on a surface of the protrusion; and
an etching step of forming the protrusion and the irregular portion by dry etching.

6. The method of claim 5, wherein the mask formation step is to form either the first etch mask or the second etch mask and form the other thereon.

7. The method of claim 5, wherein the mask formation step is to form the protrusion by etching after the formation of the first etch mask and form the second etch mask on the surface of the protrusion.

8. The method of claim 5, wherein the step for forming the second etch mask comprises:
a step of forming a material layer on the substrate; and
a step of applying heat to the material layer.

9. The method of claim 5, wherein either the first etch mask or the second etch mask is formed and the other is formed thereon,
wherein the second etch mask is formed by the step of forming the material layer and the step of applying the heat to the material layer.

10. A III-nitride semiconductor light emitting device comprising:
a substrate;
a plurality of III-nitride semiconductor layers grown over said substrate, said plurality of III-nitride semiconductor layers including an active layer for generating light by recombination of electrons and holes; and
a series of elongated protrusions formed on said substrate, said plurality of semiconductor layers being grown over said series of protrusions and said substrate, at least one of said series of protrusions having a substantially triangular or conical cross section.
